(19) United States
(12) Patent Application Publication
(10) Pub. No.: US 2008/0130234 A1
(43) Pub. Date: Jun. 5, 2008

(54) Electronic Apparatus

(76) Inventors: Daisuke Maehara, Ome-shi (JP); Yoshiaki Suzuki, Sagamihara-shi (JP)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/845,956

(22) Filed: Aug. 28, 2007

(30) Foreign Application Priority Data
Nov. 30, 2006 (JP) 2006-324626

(51) Int. Cl. H05K 7/20

(52) U.S. Cl. 361/704

(57) ABSTRACT

According to one embodiment, an electronic apparatus is provided with a first circuit board contained in a case, a heat-generating component mounted on the first circuit board, a second circuit board contained in the case and opposed to the heat-generating component, and a heat-conductive member which is interposed between the heat-generating component and the second circuit board and thermally connects the heat-generating component to the second circuit board.

### CROSS-REFERENCE TO RELATED APPLICATIONS

This application is based upon and claims the benefit of priority from Japanese Patent Application No. 2006-324626, filed Nov. 30, 2006, the entire contents of which are incorporated herein by reference.

### BACKGROUND

1. Field

One embodiment of the invention relates to an electronic apparatus mounted with a heat-generating component.

2. Description of the Related Art

An electronic apparatus, such as a portable computer, is mounted with a heat-generating component, e.g., a CPU or a graphic chip. In recent years, the integration density of semiconductors has been drastically enhanced, so that the amount of heat generated from the heat-generating component has been increased. If the operating temperature is too high, the reliability and life performance of the heat-generating component lower inevitably. Therefore, many electronic apparatuses are provided with a heat radiating structure that promotes heat radiation from the heat-generating component.

Described in Jpn. Pat. Appln. KOKAI Publication No. 10-275883 is a heat radiating structure which includes an integrated circuit device and heat-radiating member. The integrated circuit device is mounted on the upper surface of a circuit board. The heat-radiating member is thermally connected to the lower surface of the circuit board. This circuit board is penetrated from top to bottom by radiating via holes. Heat generated in the integrated circuit device is transmitted to the heat-radiating member.

In some electronic apparatuses, a plurality of circuit boards may be mounted overlapping one another. For example, a circuit board that is mounted with a heat-generating component and a heat-radiating member therefor may have to be overlain by another circuit board from a direction such that the second circuit board faces the heat-radiating member. Since the heat radiating member is interposed between the two circuit boards in this case, it is difficult to narrow a clearance between the circuit boards. If the heat-radiating member is miniaturized in order to reduce the clearance between the circuit boards, it may possibly fail to secure its necessary heat radiation performance. Thus, it is hard to reduce the thickness of an electronic apparatus that is expected to meet the aforesaid requirement.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the present invention;

FIG. 2 is an exemplary sectional view of the portable computer according to the first embodiment;

FIG. 3 is an exemplary enlarged sectional view showing a portion of the portable computer encircled by line F3 in FIG. 2;

FIG. 4 is an exemplary sectional view showing a first modification of the portable computer according to the first embodiment;

FIG. 5 is an exemplary sectional view showing a second modification of the portable computer according to the first embodiment;

FIG. 6 is an exemplary sectional view showing a third modification of the portable computer according to the first embodiment;

FIG. 7 is an exemplary sectional view showing a fourth modification of the portable computer according to the first embodiment;

FIG. 8 is an exemplary sectional view of a portable computer according to a second embodiment of the invention;

FIG. 9 is an exemplary sectional view of a portable computer according to a third embodiment of the invention;

FIG. 10 is an exemplary sectional view of a portable computer according to a fourth embodiment of the invention;

FIG. 11 is an exemplary sectional view of a portable computer according to a fifth embodiment of the invention; and

FIG. 12 is an exemplary sectional view of a portable computer according to a sixth embodiment of the invention.

### DETAILED DESCRIPTION

various embodiments according to the invention will be described hereinafter with reference to the accompanying drawings. In general, according to one embodiment of the invention, an electronic apparatus is provided with a first circuit board contained in a case, a heat-generating component mounted on the first circuit board, a second circuit board contained in the case and opposed to the heat-generating component, and a heat-conductive member which is interposed between the heat-generating component and the second circuit board and thermally connects the heat-generating component to the second circuit board.

Several embodiments of the present invention applied to portable computers will now be described with reference to the accompanying drawings.

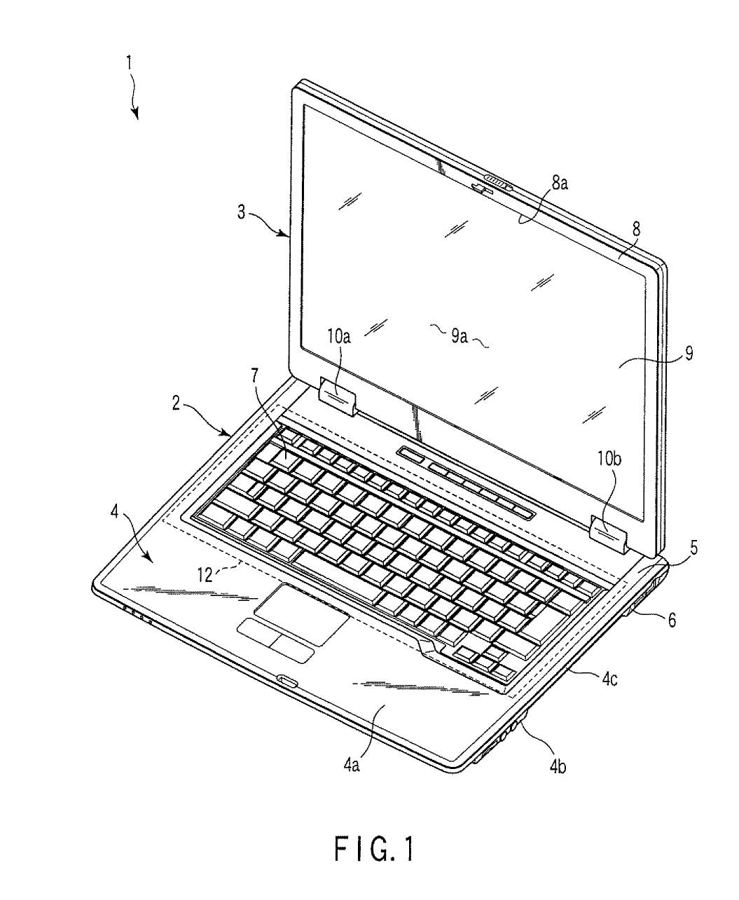

FIGS. 1 to 3 show a portable computer 1 as an electronic apparatus according to a first embodiment of the invention. As shown in FIG. 1, the portable computer 1 includes a main body 2 and a display unit 3.

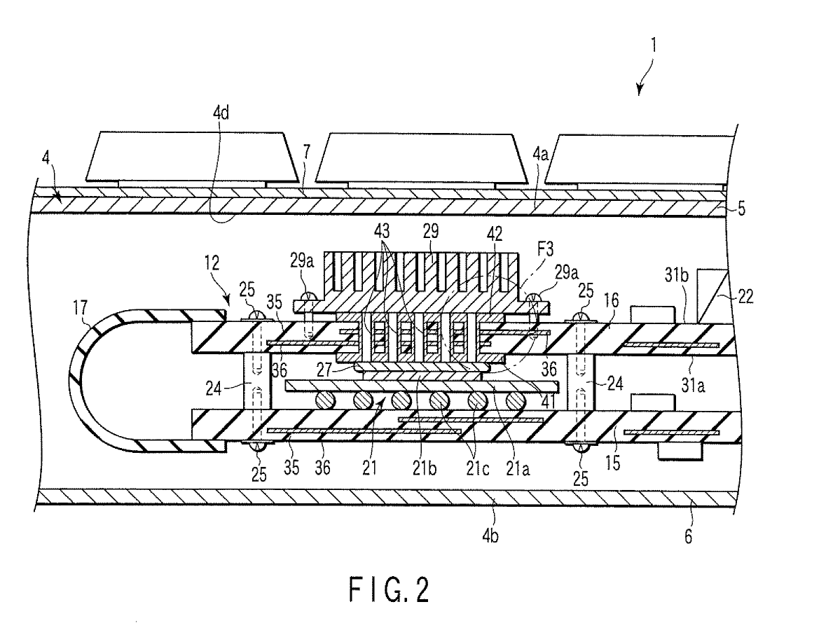

The main body 2 has a box-shaped case 4. The case 4 has an upper wall 4a, a lower wall 4b, and a peripheral wall 4c. The case 4 is divided into a case cover 5 including the upper wall 4a and a case base 6 including the lower wall 4b. The case cover 5 is combined to the case base 6 from above and removably supported by the base 6. The upper wall 4a supports a keyboard 7. The case 4 has an inner surface 4d (see FIG. 2). The inner surface 4d is exposed to a storage space that is defined in the case 4.

The display unit 3 includes a display housing 8 and a liquid crystal display module 9 therein. The display module 9 has a display screen 9a. The screen 9a is exposed to the outside of the display housing 8 through an opening 8a that opens in the front face of the housing 8.

The display unit 3 is supported on a rear end portion of the main body 2 by a pair of hinge portions 10a and 10b. Thus, the display unit 3 is swingable between a closed position in which it lies flat and covers the upper wall 4a from above and an open position in which it stands upright so that the upper wall 4a is exposed.

As shown in FIG. 1, the case 4 contains a board unit 12. As shown in FIG. 2, the board unit 12 includes a first circuit board 15, a second circuit board 16, and a flexible board 17. The first and second circuit boards 15 and 16 are rigid boards, by way of example. Alternatively, however, they may be flexible boards. If the second circuit board 16 is a rigid board, a greater heat radiation effect can be expected of it than in the case where it is a flexible board. A heat-generating component 21, such as a CPU, is mounted on the first circuit board 15. An example of the first circuit board 15 is a CPU board that is mounted with the CPU.

The heat-generating component 21 is a circuit component that generates heat during use. It may, for example, be a CPU, north bridge, memory, graphic chip, graphic controller, or power circuit. However, the heat-generating component according to the invention is not limited to this, but may be any of various circuit components that require heat radiation. An example of the heat-generating component 21 has a base substrate 21a, an IC chip 21b mounted on the base substrate 21a, and bumps 21c for electrical connection. The bumps 21c, for example, of the heat-generating component 21 are joined individually to pads on the first circuit board 15, whereby the component 21 is electrically connected to the board 15.

On the other hand, a circuit component 22, such as an I/O connector, is mounted on the second circuit board 16. An example of the second circuit board 16 is an I/O board that is mounted with the I/O connector. However, the circuit component 22 is not limited to the I/O connector but may be any other circuit component that generates less heat than the aforesaid heat-generating component 21 does.

As shown in FIG. 2, the second circuit board 16 is located between the first circuit board 15 and the inner surface 4d of the upper wall 4a. A clearance is secured between the first and second circuit boards 15 and 16, and the second circuit board 16 is laid over the first circuit board 15 in the thickness direction of the case 4 (i.e., in the vertical direction of FIG. 2). An example of the clearance between the boards 15 and 16 ranges from 2 to 3 mm or more. The second circuit board 16 is opposed to that surface of the first circuit board 15 on which the heat-generating component 21 is mounted so that the board 16 faces the component 21. In other words, the heat-generating component 21 is mounted between the circuit boards 15 and 16 that are arranged in layers.

For example, a plurality of studs 24 are provided between the first and second circuit boards 15 and 16. The circuit boards 15 and 16 are individually fixed to the studs 24 by fixing members 25 such as screws. The circuit boards 15 and 16 are mechanically coupled to each other by the studs 24. As this is done, the clearance between the circuit boards 15 and 16 is maintained so that the circuit boards 15 and 16 are kept substantially parallel to each other.

The flexible board 17 is provided ranging from the first circuit board 15 to the second circuit board 16. The circuit boards 15 and 16 are connected electrically and mechanically to each other by the board 17. The flexible board 17 is not essential to the invention and may be omitted.

A heat-conductive member 27 is interposed between the heat-generating component 21 and the second circuit board 16. The heat-conductive member 27 is formed of a material with high thermal conductivity and serves to connect the heat-generating component 21 thermally to the second circuit board 16. An example of the heat-conductive member 27 is a heat transfer sheet or heat transfer grease, which has flexibility, for example. When the circuit boards 15 and 16 are mounted overlapping each other, a clearance between the heat-generating component 21 and the second circuit board 16 fails to become constant shape, owing to twist or distortion between the circuit boards 15 and 16. Therefore, the heat-conductive member 27 that is flexible is deformed to follow the shape of the clearance between the heat-generating component 21 and the second circuit board 16, thereby preventing an unnecessary force from acting between the component 21 and the board 16. Thus, the conductive member 27 serves also as a buffer that is interposed between the component 21 and the board 16.

The second circuit board 16 is provided with a radiator 29. The radiator 29 is an example of a member for heat radiation. An example of the radiator 29 is a heat sink having a plurality of fins, or radiating sheet metal, etc. The board 16 has a first surface 31a opposed to the first circuit board 15 and a second surface 31b different from the first surface 31a. An example of the second surface 31b is formed opposite from the first surface 31a and faces the inner surface 4d of the upper wall 4a.

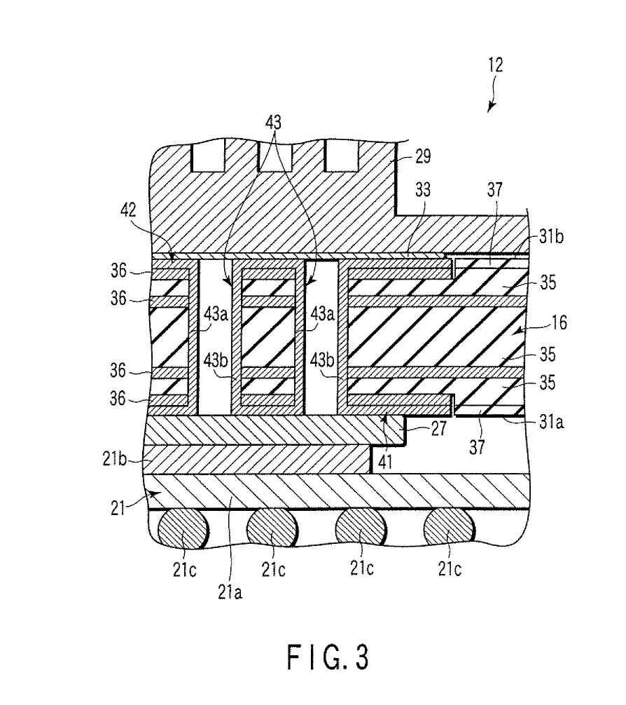

The radiator 29 is mounted on the second surface 31b of the second circuit board 16 and faces the inner surface 4d of the case 4. In other words, the radiator 29 is interposed between the inner surface 4d and the circuit board 16 that, out of the circuit boards 15 and 16, is located closer to the inner surface 4d. The radiator 29 is fixed to, for example, the second circuit board 16 by fixing members 29a, such as screws. The radiator 29 is thermally connected to the board 16. The radiator 29 is thermally connected to the heat-generating component 21 through the board 16 and the heat-conductive member 27. A heat-conductive member 33, such as a heat transfer grease or heat transfer sheet, may be provided between the radiator 29 and the second circuit board 16 (see FIG. 3).

As shown in FIG. 3, the second circuit board 16 is provided with a plurality of insulating layers 35 and a plurality of conductor layers (so-called inner layers) 36, which are alternately stacked in layers, and a solder resist layers 37 formed individually on the surfaces of the resulting laminated structure. Further, the second circuit board 16 is provided with first and second pads 41 and 42. The pads 41 and 42 are located off the solder resist layers 37 and exposed to the outside of the second circuit board 16.

The first pad 41 is provided on the first surface 31a of the second circuit board 16 and faces the heat-conductive member 27. The pad 41 is thermally connected to the conductive member 27. The second pad 42 is provided on the second surface 31b of the board 16 and faces the radiator 29. The pad 42 is thermally connected to the radiator 29.

The second circuit board 16 has plated via holes 43 (hereinafter referred to simply as via holes 43) between the first pad 41 and the second pad 42. Specifically, through holes 43a are provided extending from the first surface 31a to the second surface 31b, and plating layers 43b are formed individually on the respective inner peripheral surfaces of the through holes 43a. The via holes 43 serve to provide high heat transfer characteristics between the first and second pads 41 and 42. The heat transfer characteristics between the pads 41 and 42 can be improved by filling the via holes 43 with, for example, a heat-conductive resin or electrically conductive paste.

The conductor layers 36 formed in the second circuit board 16 are connected to the plating layers 43b of the via holes 43. The layers 36 are thermally connected to the heat-generating component 21 through the holes 43 and the heat-conductive member 27. The conductor layers 36 are formed of, for example, copper foil having high heat transfer characteristics.

The following is a description of the operation of the portable computer 1.

When the portable computer 1 is operated, the heat-generating component 21 generates heat. Some of the heat generated from the component 21 is transmitted through the heat-conductive member 27 and received by the first pad 41 of the second circuit board 16. Some of the heat received by the first pad 41 is transmitted to the conductor layers 36 of the board 16 through the via holes 43 and diffused through the conductor layers 36 into the board 16. The heat diffused in the second circuit board 16 is discharged to the outside of the board unit 12 when the board 16 functions as a heat-radiating member.

Some of the heat received by the first pad 41 is transmitted to the radiator 29 through the via holes 43 and the second pad 42. The heat transmitted to the radiator 29 is discharged to the outside of the board unit 12 through the radiator 29. As the heat is thus discharged out of the board unit 12 by the second circuit board 16 and the radiator 29, cooling of the heat-generating component 21 is promoted.

According to the portable computer 1 constructed in this manner, the electronic apparatus and the board unit can be reduced in thickness without failing to ensure heat radiation from the heat-generating component. Specifically, heat radiation from the heat-generating component 21 mounted on the first circuit board 15 can be facilitated by releasing some of the heat from the component 21 to the second circuit board 16. Further, a necessary heat radiating structure for the heat-generating component 21 can be miniaturized by utilizing the second circuit board 16 as a heat-radiating member.

More specifically, the size of the radiator 29 can be reduced correspondingly as the second circuit board 16 functions as a heat-radiating member. If the radiator 29 can be reduced in size, the clearance between the first and second circuit boards 15 and 16 can be reduced even though the radiator 29 is mounted between them. Thus, the portable computer 1 and the board unit 12 can be reduced in thickness without failing to maintain good heat radiation performance.

If the heat-conductive member 27 is flexible, high heat transfer characteristics can be secured between the heat-generating component 21 and the second circuit board 16 despite twist or distortion, if any, between the circuit boards 15 and 16. This contributes to miniaturization of a heat-radiating structure including the radiator 29. If the heat-conductive member 27 has flexibility, moreover, the heat-generating component 21 can be thermally connected to the second circuit board 16 without being damaged despite any twist or distortion between the circuit boards 15 and 16. This contributes to an improvement of the reliability of the portable computer 1.

If the radiator 29 that radiates the heat from the heat-generating component 21 is mounted on the second circuit board 16 without being mounted on the first circuit board 15, the clearance between the first and second circuit boards 15 and 16 can be made smaller than in the case where the radiator 29 is mounted directly on the heat-generating component 21, for example.

If the radiator 29 is mounted on the second surface 31b of the second circuit board 16 that does not face the first circuit board 15, a space for the radiator 29 need not be provided between the circuit boards 15 and 16. Thus, the clearance between the circuit boards 15 and 16 can be set without taking the mounting height of the radiator 29 into consideration. This helps the board unit 12 and the portable computer 1 to be reduced in thickness.

If the second circuit board 16 has the first and second pads 41 and 42, the heat transfer characteristics between the board 16 and the heat-generating component 21 and between the board 16 and the radiator 29 are improved. If the via holes 43 are arranged between the pads 41 and 42, the heat transfer characteristics between the pads 41 and 42 are improved.

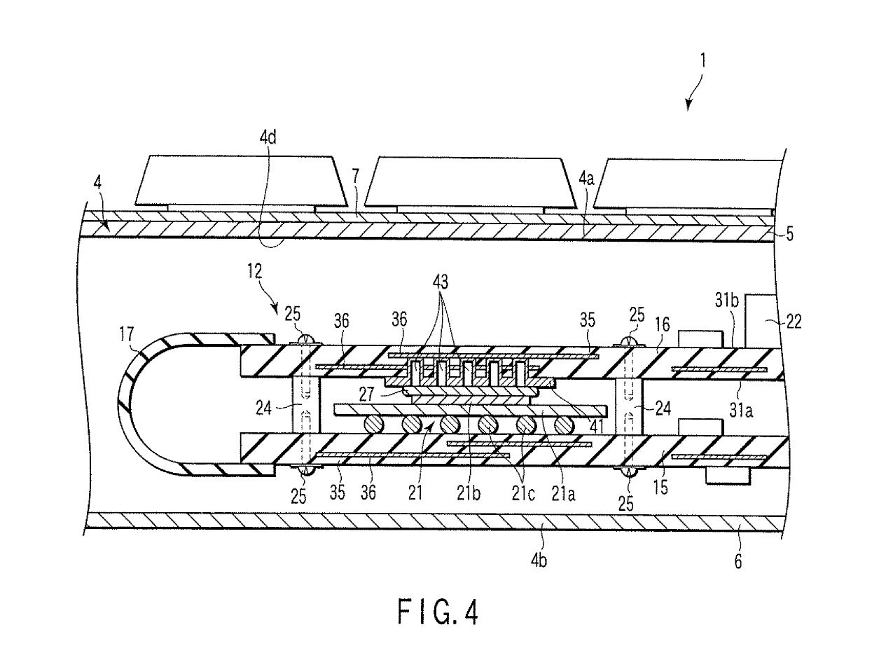

Modifications of the portable computer 1 according to the first embodiment will now be described with reference to FIGS. 4 to 7.

The radiator 29 is omitted in the portable computer 1 according to a modification shown in FIG. 4. The radiator 29 can be omitted if the second circuit board 16 functions as a heat-radiating member that ensures satisfactory heat radiation from the heat-generating component 21.

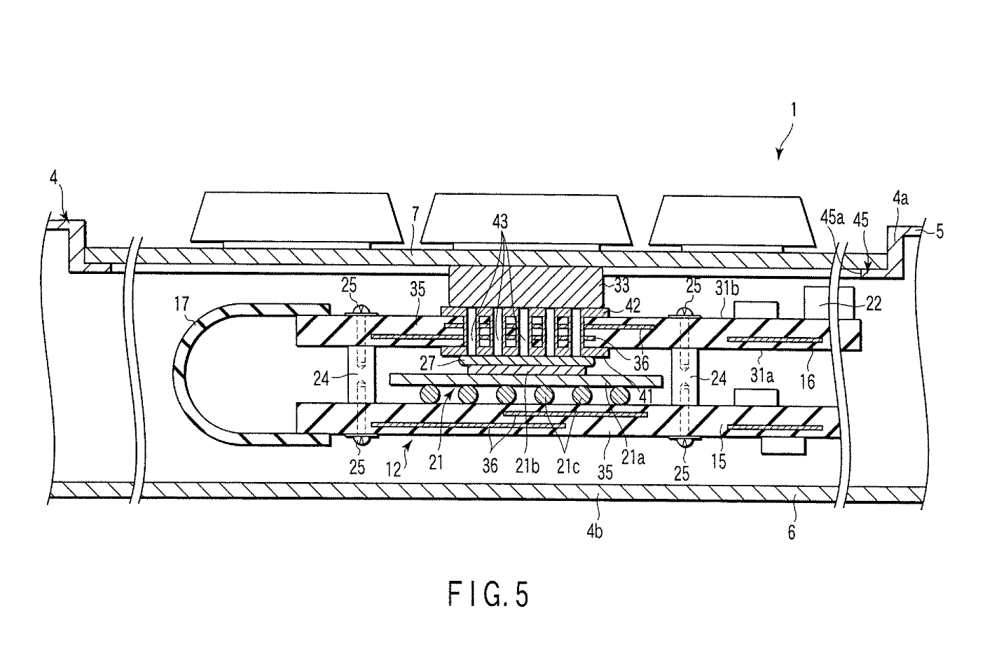

The portable computer 1 according to a modification shown in FIG. 5 includes a keyboard mounting portion 45 on which the keyboard 7 is set. The keyboard mounting portion 45 has an opening 45a that opens in the case 4. The keyboard 7 includes, for example, a metallic shield plate having high heat transfer characteristics. The keyboard 7 has its lower surface exposed to the interior of the case 4 through the opening 45a. The heat-conductive member 33 is interposed between the second circuit board 16 and the keyboard 7. Some of the heat generated from the heat-generating component 21 is transmitted to the keyboard 7 through the board 16 and discharged to the outside of the board unit 12 as the keyboard 7 functions as a heat radiating member. The keyboard 7 is an example of the member for heat radiation.

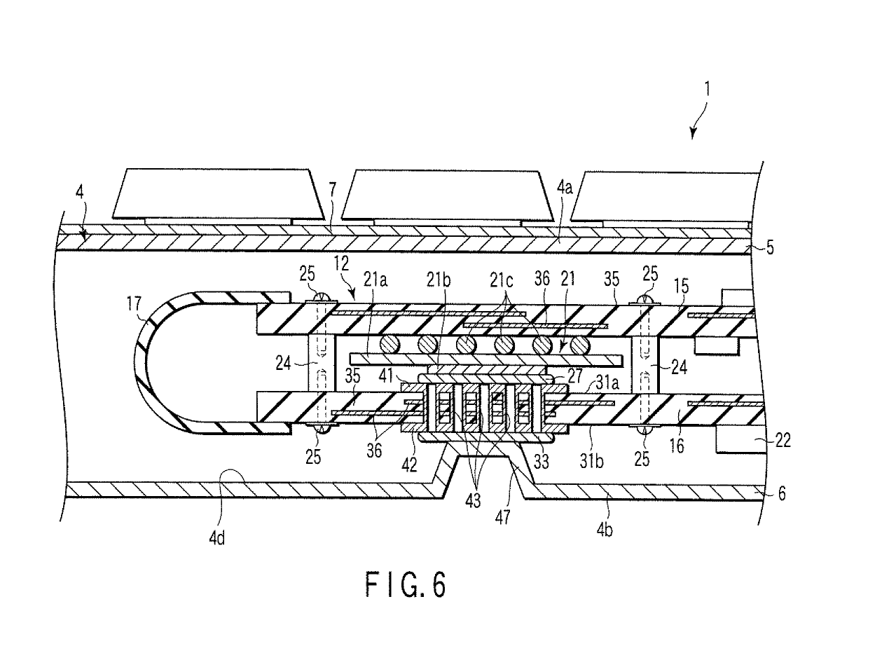

The portable computer 1 according to a modification shown in FIG. 6 has a heat-receiving portion 47 in, for example, the case base 6. The heat-receiving portion 47 rises from the lower wall 4b of the case 4 and faces the second circuit board 16. The heat-conductive member 33 is interposed between the board 16 and the heat-receiving portion 47 of the case 4. An example of the case 4 is made of magnesium alloy. Some of the heat generated from the heat-generating component 21 is transmitted to the case base 6 through the board 16 and discharged to the outside of the board unit 12 as the case 4 functions as a heat radiating member. The case 4 is an example of the member for heat radiation.

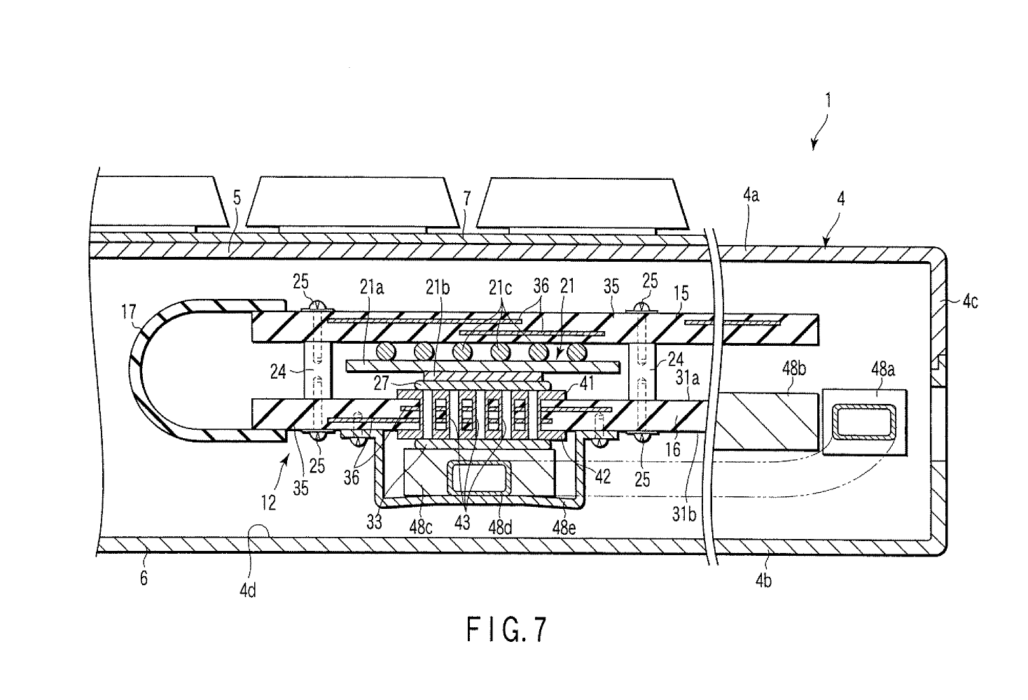

The portable computer 1 according to a modification shown in FIG. 7 includes radiator fins 48a, cooling fan 48b, heat-receiving block 48c, heat pipe 48d, and fixing member 48e. The heat pipe 48d and the heat-receiving block 48c are examples of the member for heat radiation. Some of the heat generated from the heat-generating component 21 is transmitted to the heat-receiving block 48c through the second circuit board 16 and delivered to the radiator fins 48a through the heat pipe 48d. The heat moved to the radiator fins 48a is discharged to the outside of the case 4 by the cooling fan 48b. The portable computer 1 according to any of the modifications of FIGS. 4 to 7 described above can produce the same effects of the portable computer according to the aforementioned first embodiment. Although the radiator 29 is given and explained as an example of the member for heat radiation in second to sixth embodiments described below, the aforementioned various members for heat radiation are also applicable to the second to sixth embodiments.

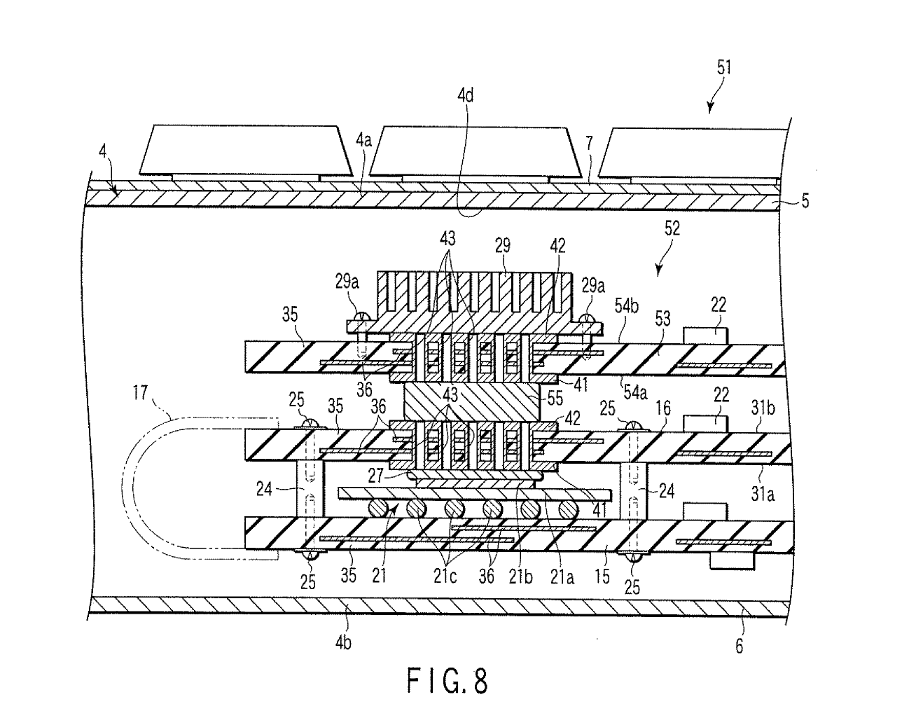

A portable computer 51 as an electronic apparatus according to a second embodiment of the invention will now be described with reference to FIG. 8. Like numbers are used to designate those components of this computer and the portable computer 1 according to the first embodiment which have the same functions, and a description thereof is omitted herein.

A board unit 52 of the portable computer 51 includes a third circuit board 53 as well as first and second circuit boards 15 and 16. The third circuit board 53 is provided between an inner surface 4d of an upper wall 4a of a case 4 and a second circuit board 16. In other words, the first, second, and third circuit boards 15, 16 and 53 are spaced from and overlap one another. The third circuit board 53 has a third surface 54a opposed to the second circuit board 16 and a fourth surface 54b formed opposite from the third surface 54a and facing the inner surface 4d of the case 4. The third and fourth surfaces 54a and 54b are provided with first and second pads 41 and 42, respectively. Via holes 43 are provided between the pads 41 and 42.

A heat-conductive member 55 is interposed between the second pad 42 of the second circuit board 16 and the first pad 41 of the third circuit board 53. The third circuit board 53 is thermally connected to the board 16 through the conductive member 55. The material of the heat-conductive member 55 may be the same as or different from that of the heat-conductive member 27.

A radiator 29 is mounted on the fourth surface 54b of the third circuit board 53. The radiator 29 faces the inner surface 4d of the case 4. In other words, the radiator 29 is interposed between the inner surface 4d and the circuit board 53 that, cut of the circuit boards 15, 16 and 53, is located closest to the inner surface 4d. The radiator 29 is thermally connected to the third circuit board 53. The radiator 29 is thermally connected to a heat-generating component 21 through the second and third circuit boards 16 and 53 that are located between the radiator 29 and the component 21. Clearances of at least 2 mm to 3 mm are provided between the first, second, and third circuit boards 15, 16 and 53 so that air between the boards can easily flow to prevent heat from being confined.

According to the portable computer 51 constructed in this manner, the electronic apparatus and the board unit can be reduced in thickness without failing to ensure heat radiation from the heat-generating component. Thus, a heat-radiating structure including the radiator 29 can be reduced in size by utilizing the second and third circuit boards 16 and 53 as heat radiating members. Further, the radiator 29 can be made smaller than that of the portable computer 1 according to the first embodiment by using the plurality of circuit boards 16 and 53 as heat radiating members. Thus, the portable computer 1 and the board unit 52 can be reduced in thickness without failing to maintain good heat radiation performance.

The radiator 29 that radiates heat from the heat-generating component 21 is interposed between the inner surface 4d of the case 4 and the third circuit board 53 that is located closest to the inner surface 4d without being mounted on the first circuit board 15. In this way, the clearances between the first, second, and third circuit boards 15, 16 and 53 can be reduced without taking a mounting space for the radiator 29 into consideration. This helps the board unit 52 and the portable computer 51 to be reduced in thickness. The third circuit board 53 is not limited to one in number, but a plurality of third circuit boards 53 may be provided.

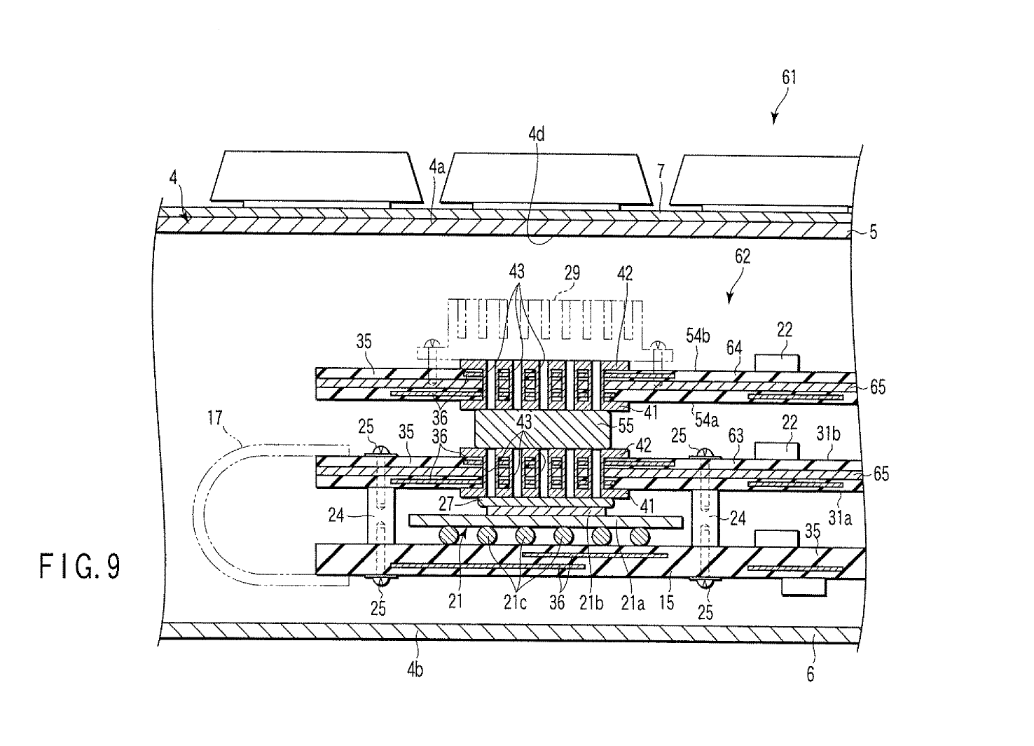

A portable computer 61 as an electronic apparatus according to a third embodiment of the invention will now be described with reference to FIG. 9. Like numbers are used to designate those components of this computer and the portable computers 1 and 51 according to the first and second embodiments which have the same functions, and a description thereof is omitted herein.

A board unit 62 of the portable computer 61 includes first, second, and third circuit board 15, 63 and 64. The second and third circuit boards 63 and 64 are so-called metal core boards, which each have a metal core layer 65 therein. Copper, aluminum, iron, etc. are examples of the material of the metal core layer 65.

According to the portable computer 61 constructed in this manner, the electronic apparatus and the board unit can be reduced in thickness without failing to ensure heat radiation from a heat-generating component, for the same reason for the portable computer 51 according to the second embodiment.

A metal core board is higher in heat radiation characteristics than a conventional glass epoxy resin board. If metal core boards are used for the second and third circuit boards 63 and 64, the heat radiation effect of the circuit boards 63 and 64 is enhanced, so that the radiator 29 can be further reduced in size or may be omitted, in some cases. This helps the portable computer 61 and the board unit 62 to be reduced in thickness.

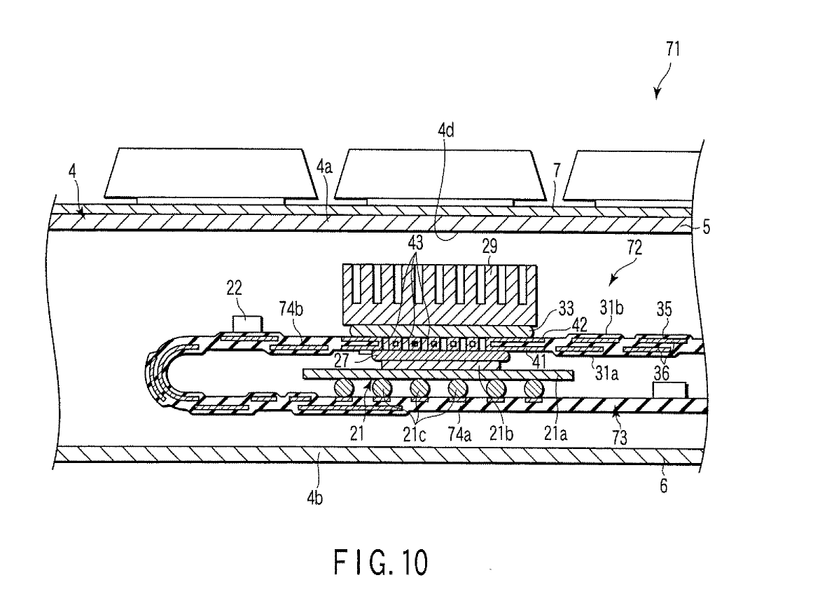

A portable computer 71 as an electronic apparatus according to a fourth embodiment of the invention will now be described with reference to FIG. 10. Like numbers are used to designate those components of this computer and the portable computer 1 according to the first embodiment which have the same functions, and a description thereof is omitted herein.

A board unit 72 of the portable computer 71 includes a circuit board 73 and a heat-generating component 21. An example of the circuit board 73 is a flexible printed circuit board and has flexibility. The circuit board 73 has a first region 74a and a second region 74b. The heat-generating component 21 is mounted in the first region 74a. The second region 74b is turned back over the first region 74a and faces the heat-generating component 21 from the side opposite from the first region 74a. Thus, the first and second regions 74a and 74b overlap each other in the thickness direction of the case 4. A heat-conductive member 27 is interposed between the heat-generating component 21 and the second region 74b.

The second region 74b of the circuit board 73 has a first surface 31a opposed to the first region 74a and a second surface 31c that is formed on the side opposite from the first surface 31a and faces an inner surface 4d. A radiator 29 is mounted on the second surface 31b of the second region 74b and faces the inner surface 4d. The radiator 29 is thermally connected to the second region 74b. The radiator 29 is also thermally connected to the heat-generating component 21 through the second region 74b and the heat-conductive member 27.

According to the portable computer 71 constructed in this manner, the electronic apparatus and the board unit can be reduced in thickness without failing to ensure heat radiation from the heat-generating component. Specifically, some of heat from the heat-generating component 21 mounted in the first region 74a of the circuit board 73 is radiated by means of the radiator 29 in the second region 74b. In this way, a clearance between the first and second regions 74a and 74b can be reduced without taking a mounting space for the radiator 29 into consideration. This helps the portable computer 71 and the board unit 72 to be reduced in thickness.

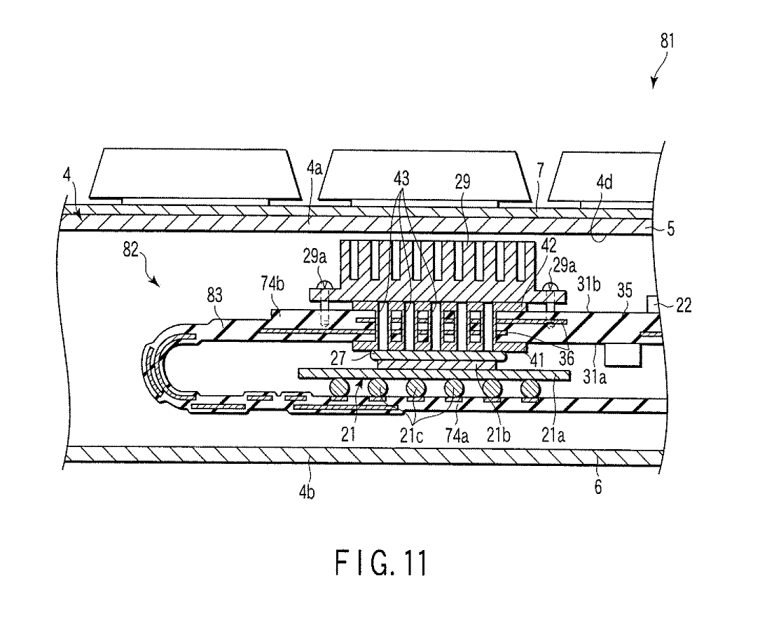

A portable computer 81 as an electronic apparatus according to a fifth embodiment of the invention will now be described with reference to FIG. 11. Like numbers are used to designate those components of this computer and the portable computers 1 and 71 according to the first and fourth embodiments which have the same functions, and a description thereof is omitted herein.

A board unit 82 of the portable computer 81 includes a circuit board 83. The circuit board 83 has a first region 74a and a second region 74b. The circuit board 83 is a so-called rigid-flexible board, of which the second region 74b is formed of a rigid board.

According to the portable computer 81 constructed in this manner, the electronic apparatus and the board unit can be reduced in thickness without failing to ensure heat radiation from the heat-generating component. Specifically, a necessary heat radiating structure for the heat-generating component 21 can be miniaturized by utilizing the second region 74b that is formed of the rigid board as a heat-radiating member to which some of heat from the component 21 is released. Thus, a heat-radiating structure including a radiator 29 can be reduced in size, and the portable computer 81 and the board unit 82 can be reduced in thickness. The radiator 29 may be omitted if the second region 74b can produce a satisfactory heat radiation effect.

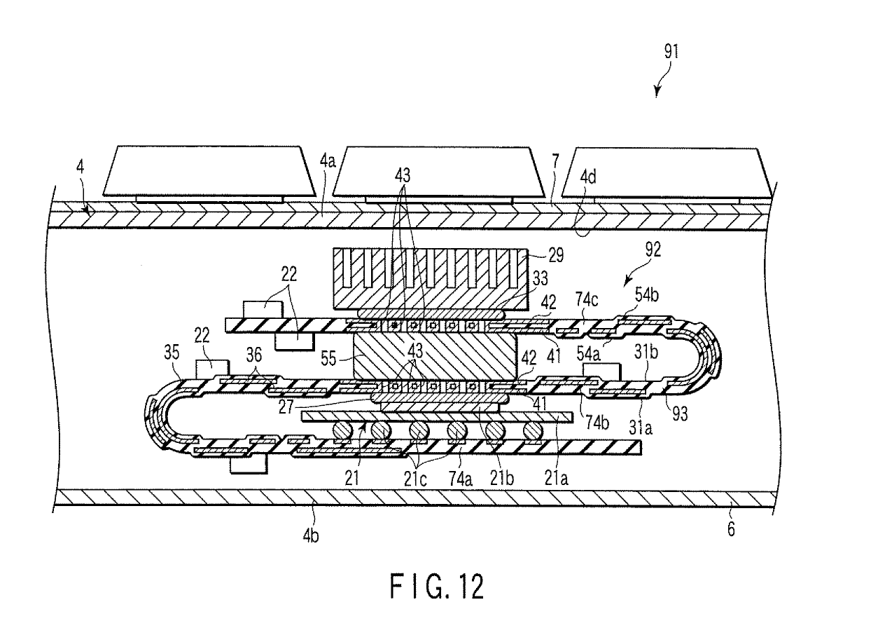

A portable computer 91 as an electronic apparatus according to a sixth embodiment of the invention will now be described with reference to FIG. 12. Like numbers are used to designate those components of this computer and the portable computers 1 and 71 according to the first and fourth embodiments which have the same functions, and a description thereof is omitted herein.

A board unit 92 of the portable computer 91 includes a circuit board 93. The circuit board 93 has a third region 74c. The third region 74c is further turned back over a second region 74b and faces the second region 74b from the side opposite from a first region 74a. The third region 74c has a third surface 54a opposed to the second region 74b and a fourth surface 54b opposed to an inner surface 4d of a case 4. A heat-conductive member 55 is interposed between the second and third regions 74b and 74c. A radiator 29 is mounted on the fourth surface 54b of the third region 74c and faces the inner surface 4d. The radiator 29 is thermally connected to the third region 74c. The radiator 29 is also thermally connected to a heat-generating component 21 through the second and third regions 74b and 74c, a heat-conductive member 27, and the heat-conductive member 55.

According to the portable computer 91 constructed in this manner, the electronic apparatus and the board unit can be reduced in thickness without failing to ensure heat radiation from the heat-generating component. Specifically, some of heat from the heat-generating component 21 mounted in the first region 74a of the circuit board 93 is radiated by means of the radiator 29 in the third region 74c. In this way, clearances between the first and second regions 74a and 74b and between the second and third regions 74b and 74c can be reduced without taking a mounting space for the radiator 29 into consideration. This helps the portable computer 91 and the board unit 92 to be reduced in thickness.

Although the portable computers 1, 51, 61, 71, 81 and 91 and the board units 12, 52, 62, 72, 82 and 92 according to the first to sixth embodiments have been described herein, it is to be understood that the invention is not limited to these embodiments. The components according to the first to sixth embodiments may be suitably combined for application.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a case;
a first circuit board contained in the case;
a heat-generating component mounted on the first circuit board;
a second circuit board contained in the case and opposed to the heat-generating component; and
a heat-conductive member which is interposed between the heat-generating component and the second circuit board and thermally connects the heat-generating component to the second circuit board.

2. An electronic apparatus according to claim 1, wherein the heat-conductive member has flexibility and is configured to be deformed to follow the shape of a clearance between the heat-generating component and the second circuit board.

3. An electronic apparatus according to claim 1, further comprising:
a member for heat radiation mounted on a surface of the second circuit board different from that surface which faces the first circuit board, the member for heat-radiation being thermally connected to the heat-generating component through the second circuit board.

4. An electronic apparatus according to claim 1, further comprising:
at least one third circuit board contained in the case; and
another heat-conductive member which thermally connects the third circuit board to the second circuit board.

5. An electronic apparatus according to claim 4, further comprising:
a member for heat radiation,
wherein the case includes an inner surface exposed to the interior of the case, the third circuit board is located between the second circuit board and the inner surface of the case, and the member for heat radiation is mounted on that surface of the third circuit board which faces the inner surface, the member for heat radiation being thermally connected to the heat-generating component through the third and second circuit boards.

6. An electronic apparatus according to claim 1, wherein the second circuit board is a metal core board.

7. An electronic apparatus comprising:
a case;
a heat-generating component contained in the case;
a circuit board which is contained in the case, has flexibility at least in a part thereof, and includes a first region in which the heat-generating component is mounted and a second region which is turned back over the first region, the second region facing the heat-generating component from the side opposite from the first region; and
a heat-conductive member which is interposed between the heat-generating component and the second region of the circuit board and thermally connects the heat-generating component to the second region of the circuit board.

8. An electronic apparatus according to claim 7, further comprising:
a member for heat radiation, mounted on a surface of the second region of the circuit board different from that surface which faces the first region, the member for heat radiation being thermally connected to the heat-generating component through the second region of the circuit board.

9. An electronic apparatus according to claim 7, wherein the second region of the circuit board is formed of a rigid board.
